(19) United States
(12) Patent Application Publication
(10) Pub. No.: US 2020/0243310 A1
(43) Pub. Date: Jul. 30, 2020

(54) PLASMA PROCESSING APPARATUS

(71) Applicant: ULVAC, INC., Chigasaki-shi (JP)

(72) Inventors: Tsuyoshi KAGAMI, Chigasaki-shi (JP); Takahiro NANBA, Chigasaki-shi (JP); Hiroki YAMAMOTO, Chigasaki-shi (JP); Shinji KOHARI, Chigasaki-shi (JP); Naoki MORIMOTO, Chigasaki-shi (JP)

(21) Appl. No.: 16/492,373

(22) PCT Filed: Oct. 12, 2018
(86) PCT No.: PCT/JP2018/038172

§ 371 Date: Sep. 9, 2019

(30) Foreign Application Priority Data
Oct. 16, 2017 (JP) 2017-200289

(51) Int. Cl. H01J 37/32; H01L 21/67

(52) U.S. Cl. CPC H01J 37/32834; H01L 21/67069; H01J 2237/3343; H01J 37/32541; H01J 37/3244; H01J 37/32715

(57) ABSTRACT

A plasma processing apparatus of the invention includes: a chamber that has an internal space able to be depressurized and is configured such that a processing object is subjected to plasma treatment in the internal space; a first electrode that is disposed in the chamber and on which the processing object is to be mounted; a first power supply that applies a bias voltage of negative potential to the first electrode; a spiral shaped second electrode that is disposed outside the chamber and is disposed so as to face the first electrode with an upper lid of the chamber interposed therebetween; a second electrode that applies a high-frequency voltage to the second electrode. A plate having a shape forming a space and a cover provided to cover the plate are stacked in order and disposed between the first electrode and the processing object.

### TECHNICAL FIELD

The present invention relates to a plasma processing apparatus capable of uniformly etching a substrate or a substrate on which a thin film or the like is formed (hereinafter, also referred to as “processing object”, more particularly, relates to a plasma processing apparatus used in the case of forming a film on a semiconductor substrate made of silicon, quartz, a glass, or the like by a sputtering method or a chemical vapor deposition method, in the case of etching the substrate including the formed film, or in the case of etching a natural oxide film or an undesired substance which is generated on a substrate surface.

This application claims priority from Japanese Patent Application No. 2017-200289 filed on Oct. 16, 2017, the contents of which are incorporated herein by reference in their entirety.

### BACKGROUND ART

In etching treatment, ions generated from plasma are accelerated due to a negative self-bias voltage and collide against a processing object. In such etching treatment, in accordance with an increase in the size of a substrate that is the processing object, it becomes difficult to maintain uniformity in etching on a surface of the substrate.

In contrast, a plasma processing apparatus and a plasma treatment method are disclosed which separate an electrode and include a plurality of high-frequency power supplies in order to carry out etching by uniform plasma treatment on a surface of a substrate (for example, Patent Document 1). In addition, a plasma treatment method and a plasma processing apparatus are disclosed which include a plurality of high-frequency power supplies having different frequency and thereby carry out excellent plasma treatment on a surface of a substrate (for example, Patent Document 2).

However, in the plasma processing apparatus disclosed in Patent Document 1 or Patent Document 2, the electrode configuration thereof is complicated, maintenance therefor is deteriorated, and it is necessary to arrange a plurality of power supplies. Accordingly, there are problems in that the footprint of the apparatus increases and the cost required to operate the apparatus increases. Consequently, development of a plasma treatment method and a plasma processing apparatus provides excellent maintenance and can inexpensively realize the same effect as the above-described effect have been expected.

### PRIOR ART DOCUMENTS

### Patent Documents

(Patent Document 1) Japanese Unexamined Patent Application, First Publication No. 2011-228436
(Patent Document 2) Japanese Unexamined Patent Application, First Publication No. 2008-244429

### SUMMARY OF THE INVENTION

### Problems to be Solved by the Invention

The invention was conceived in view of the above-described conventional circumstances and has an object thereof to provide a plasma processing apparatus that provides excellent maintenance and can uniformly etch a processing object.

### Means for Solving the Problems

A plasma processing apparatus according to an aspect of the invention, includes: a chamber that has an internal space able to be depressurized and is configured such that a processing object is subjected to plasma treatment in the internal space; a first electrode (support base) that is disposed in the chamber and on which the processing object is to be mounted; a first power supply that applies a bias voltage of negative potential to the first electrode; a spiral shaped second electrode (antenna coil) that is disposed outside the chamber and is disposed so as to face the first electrode with an upper lid of the chamber interposed therebetween; a second electrode that applies a high-frequency voltage to the second electrode; a gas introduction device that introduces a processing gas into an inside of the chamber; and a pumping device that depressurizes the inside of the chamber. A plate (adjustment plate) having a shape forming a space and a cover (electrode cover) provided to cover the plate are stacked in order and disposed between the first electrode and the processing object.

In the plasma processing apparatus according to the aspect of the invention, the space may be formed by: an inner surface forming a recessed portion provided on the plate; and one surface of the cover which is located close to the plate.

In the plasma processing apparatus according to the aspect of the invention, the space may be disposed at a center region of the cover.

In the plasma processing apparatus according to the aspect of the invention, the space may be disposed at an outer edge region of the cover.

The plasma processing apparatus according to the aspect of the invention may further include a spacer (dielectric) disposed inside the space.

### Effects of the Invention

In the plasma processing apparatus according to the aspect of the invention, the plate (adjustment plate) having a shape forming a space and the cover (electrode cover) provided to cover the plate are stacked in order and disposed between the first electrode and the processing object. Accordingly, only by inserting and disposing the plate forming the space into the inside a substrate mounting unit configured so that the first electrode, the plate, and the cover are stacked, a structure in which a space is provided between the processing object and the first electrode is obtained.

According to this structure, it is possible to adjust impedance at an optional position by changing the position at which the space is provided, the size thereof, or the like. For this reason, in the plasma processing apparatus according to the aspect of the invention, it is possible to carry out uniform plasma treatment on a surface of the substrate by negative potential bias. Additionally, the plasma processing apparatus according to the aspect of the invention naturally obtains the aforementioned effect only by replacing the plate. As a result, it contributes to provision of a plasma processing apparatus that provides excellent maintenance.

In the plasma processing apparatus according to the aspect of the invention, the space is formed by: an inner surface forming a recessed portion provided on the plate; and one surface of the cover which is located close to the plate. That is, in the plasma processing apparatus, only by stacking and disposing the cover on the plate having the recessed portion provided thereon, it is possible to form the space. Accordingly, it is possible to easily change and adjust the space only by determining the position of the recessed portion to be provided on the plate on the center region of the cover or the outer edge region of the cover.

The plasma processing apparatus according to the aspect of the invention may include the spacer (dielectric) disposed inside the space. The substrate mounting unit configured so that the first electrode, the plate, and the cover are stacked is formed of a conductor. In a state where a processing object is in direct contact with the substrate mounting unit formed of such conductor, in some cases, a problem occurs in that a plasma treatment profile on a surface of the substrate is degraded due to this effect. In contrast, since the plasma processing apparatus has the configuration including the spacer (dielectric) provided inside the space, it is possible to solve the above problem. Therefore, the invention contributes to an inexpensive and simplified plasma processing apparatus.

However, when the stage serving as an electrode (conductor) is in direct contact with the substrate, a profile is degraded due to this effect. In contrast, in the plasma processing apparatus according to the aspect of the invention, by providing a dielectric layer (buffer layer) between the adjustment plate and the substrate, excellent plasma treatment can be obtained. Therefore, the invention contributes to an inexpensive and simplified plasma processing apparatus.

In the plasma processing apparatus according to the aspect of the invention, it is preferable that the adjustment plate have a shape corresponding to an etching rate of a substrate to be mounted. In the case where the shape of the adjustment plate is a recessed shape, the outer-peripheral portion thereof is reduced in thickness, and a space is provided between the substrate and the adjustment plate. In the case where the shape of the adjustment plate is a projected shape, the center portion thereof is reduced in thickness, and a space is provided between the substrate and the adjustment plate. Accordingly, it is possible to carry out plasma treatment with a uniform bias on a surface of the substrate.

### BRIEF DESCRIPTION OF THE DRAWINGS

FIG. 1 is a schematic cross-sectional view showing a plasma processing apparatus according to a first embodiment of the invention.

FIG. 2 is an enlarged schematic cross-sectional view showing a substrate mounting unit provided in the plasma processing apparatus according to the first embodiment of the invention.

FIG. 3 is an enlarged schematic cross-sectional view showing the substrate mounting unit according to the first embodiment.

FIG. 4 is an enlarged schematic cross-sectional view showing a substrate mounting unit according to a second embodiment.

FIG. 5 is an enlarged schematic cross-sectional view showing a substrate mounting unit according to a third embodiment.

FIG. 6 is an enlarged schematic cross-sectional view showing a substrate mounting unit according to a fourth embodiment.

FIG. 7A is a graph showing an etching rate map in the case of using a plate having a shape forming a space which is shallow and narrow.

FIG. 7B is a graph showing an etching rate map in the case of using a plate of the invention having a shape forming a space which is deep and wide.

FIG. 8 is a graph showing a relationship between the position from the substrate center and a change rate of the etching rate calculated from the graph shown in FIG. 7B.

FIG. 9A is an enlarged schematic cross-sectional view showing an adjustment plate in the case where a space is not provided.

FIG. 9B is an enlarged schematic cross-sectional view showing an adjustment plate in the case where a space is provided.

FIG. 9C is an enlarged schematic cross-sectional view showing an adjustment plate in the case where a space is provided.

FIG. 9D is an enlarged schematic cross-sectional view showing an adjustment plate in the case where a space is provided.

FIG. 9E is an enlarged schematic cross-sectional view showing an adjustment plate in the case where a space is provided.

FIG. 10 is a graph showing a relationship between the position from the substrate center and a normalized etching rate.

### EMBODIMENTS FOR CARRYING OUT THE INVENTION

Hereinafter, a plasma processing apparatus according to one embodiment of the invention will be described with reference to drawings.

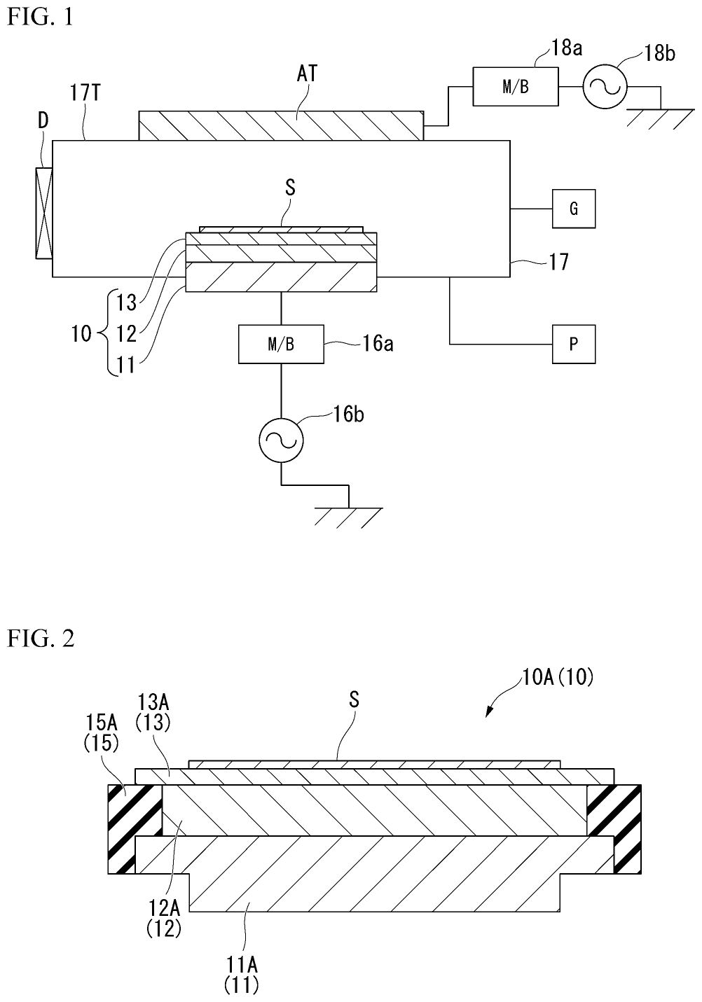

FIG. 1 is a schematic cross-sectional view showing a plasma processing apparatus according to the embodiment.

The plasma processing apparatus shown in FIG. 1 includes a chamber 17 that has an internal space able to be depressurized and is configured such that a processing object (substrate S) is subjected to plasma treatment in the internal space. The chamber 17 is connected to a multichamber apparatus (not shown in the figure) with an isolation valve D interposed therebetween.

The chamber 17 includes: a gas introduction device G that introduces a processing gas into the inside of the chamber; and a pumping device P that reduces a pressure inside the chamber.

A first electrode (support base) 11 on which the processing object is to be mounted is disposed at the lower side inside the chamber 17. A first matching box (M/B) 16a and the first electrode 11 are disposed outside the chamber 17. The first power supply 16b is electrically connected to the first electrode 11 via the first matching box (M/B) 16a and applies a bias voltage of negative potential to the first electrode 11.

A plate (adjustment plate) 12 and a cover (electrode cover) 13 are stacked in this order on the first electrode 11 inside the chamber 17. The first electrode 11, the plate 12, and the cover 13 constitute a substrate mounting unit 10. The substrate S serving as the processing object is to be mounted on the cover (electrode cover) 13. For example, operation of opening and closing the isolation valve D is carried out, and entering and taking out of the substrate S is carried out between the multichamber apparatus and (not shown in the figure) and the chamber 17 by use of a robot hand (not shown in the figure).

A spiral shaped second electrode (antenna coil) AT is arranged outside the chamber 17 at the position opposed to the first electrode 11. The second electrode AT is disposed so as to face the first electrode 11 with an upper lid 17T of the chamber interposed therebetween. A second electrode 18b that applies a high-frequency voltage is electrically connected to the second electrode AT via a second matching box (M/B) 18a.

FIG. 2 is an enlarged schematic cross-sectional view showing the substrate mounting unit 10 provided in the plasma processing apparatus shown in FIG. 1. A plate 12A (12) shown in FIG. 2 represents a state before “a shape forming a space” of the characterizing portion of the invention is provided (hereinbelow, referred to as a conventional state).

In FIG. 2, a substrate mounting unit 10A is constituted of a first electrode 11A, the plate 12A, and a cover 13A. In the substrate mounting unit 10A, an insulation portion (insulation block) 15A is disposed so as to cover the side surfaces of the plate 12A and the cover 13A.

### First Embodiment

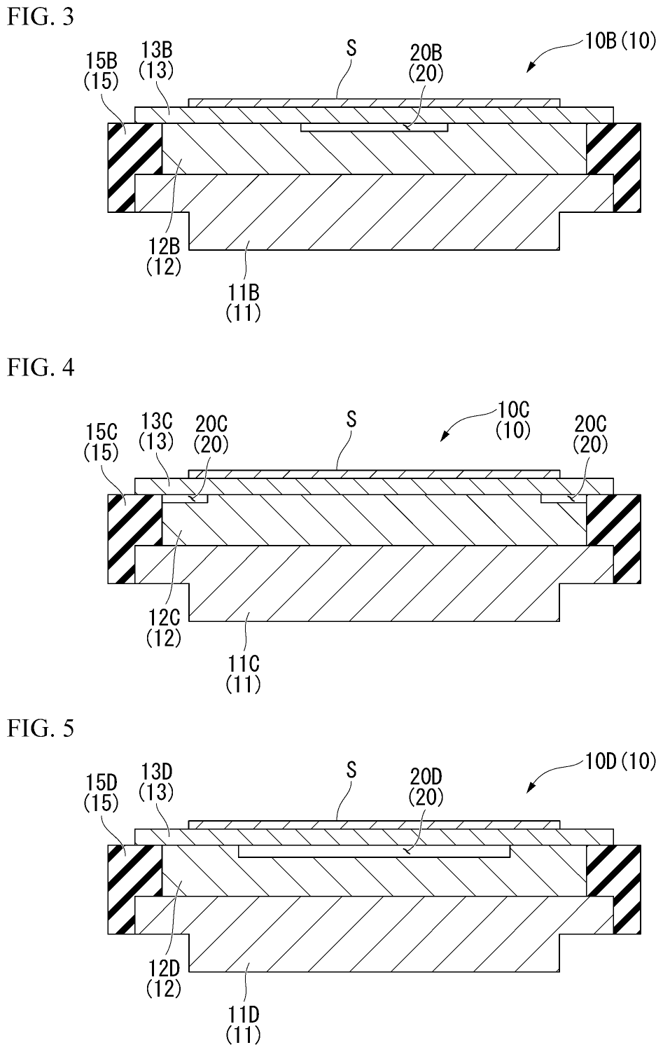

FIG. 3 is an enlarged schematic cross-sectional view showing a substrate mounting unit provided in a plasma processing apparatus according to the first embodiment. A substrate mounting unit 10 shown in FIG. 3 represents a state where “a shape forming a space” of the characterizing portion of the invention is provided.

As shown in FIG. 3, in a substrate mounting unit 10B according to the first embodiment, a plate 12B has “a shape forming a space”. Particularly, in the substrate mounting unit 10B, a recessed portion is provided at a center region of the plate 12B. A cover 13B is stacked on the plate 12B and therefore a space 20B (20) is formed at the region corresponding to the recessed portion. In the configuration example of the substrate mounting unit 10B shown in FIG. 3, a recessed portion having a predetermined depth d1 is provided at the center region on the top surface of the plate 12B, and the space 20B (20) is positioned between the cover 13B and the plate 12B. The other configuration of the substrate mounting unit 10B is the same as the aforementioned “conventional state (refer to FIG. 2)”.

According to the configuration of the first embodiment, since the substrate mounting unit 10B includes the space 20B (20), it is possible to adjust impedance of the center region of the plate 12B. Because of this, according to the first embodiment, it is possible to control plasma treatment with respect to the central region of the substrate. As a result, it is possible to carry out uniform plasma treatment on a surface of the substrate by negative potential bias.

### Second Embodiment

FIG. 4 is an enlarged schematic cross-sectional view showing a substrate mounting unit provided in a plasma processing apparatus according to the second embodiment. A substrate mounting unit 10 shown in FIG. 4 represents a state where “a shape forming a space” of the characterizing portion of the invention is provided.

As shown in FIG. 4, in a substrate mounting unit 10C according to the second embodiment, a plate 12C has “a shape forming a space”. Particularly, in the substrate mounting unit 10C, a recessed portion is disposed at the outer edge region of the plate 12C. A cover 13C is stacked on the plate 12C and therefore a space 20C (20) is formed at the region corresponding to the recessed portion. In the configuration example of the substrate mounting unit 10C shown in FIG. 4, a recessed portion having a predetermined depth d2 is provided at the outer edge region on the top surface of the plate 12C, and the space 20C (20) surrounded by the cover 13C, the plate 12C, and an insulation portion 15 is provided thereat. The other configuration of the substrate mounting unit 10C is the same as the aforementioned “conventional state (refer to FIG. 2)”.

According to the configuration of the second embodiment, since the substrate mounting unit 10C includes the space 20C (20), it is possible to adjust impedance of the outer edge region of the plate 12C. Because of this, according to the second embodiment, it is possible to control plasma treatment with respect to the outer-peripheral portion of the substrate. As a result, it is possible to carry out uniform plasma treatment on a surface of the substrate by negative potential bias. Furthermore, in the case of applying the space 20C of the substrate mounting unit 10B according to the first embodiment, it is possible to adjust impedance of both the center region and the outer edge region of the plate 12.

### Third Embodiment

FIG. 5 is an enlarged schematic cross-sectional view showing a substrate mounting unit provided in a plasma processing apparatus according to the third embodiment. A substrate mounting unit 10 shown in FIG. 5 represents a state where “a shape forming a space” of the characterizing portion of the invention is provided.

As shown in FIG. 5, in a substrate mounting unit 10D according to the third embodiment, a plate 12D has “a shape forming a space”. Particularly, in the substrate mounting unit 10D, a recessed portion is provided at a center region of the plate 12D. In the substrate mounting unit 10D, a cover 13D is stacked on the plate 12D and therefore a space 20D (20) is formed at the region corresponding to the recessed portion. In the configuration example of the substrate mounting unit 10D shown in FIG. 5, a recessed portion having a predetermined depth d3 is provided at the center region on the top surface of the plate 12D, and the space 20D (20) is positioned between the cover 13D and the plate 12D. As compared with the region on which the space 20B (20) is provided in the aforementioned first embodiment, the third embodiment is different from the first embodiment in that the region on which the space 20D (20) of the third embodiment is provided has a wider area. The other configuration of the substrate mounting unit 10D is the same as the above-described first embodiment.

According to the configuration of the third embodiment, the substrate mounting unit 10D can adjust impedance of the center region of the plate 12D by the space 20D (20). In the third embodiment, the region on which the space 20D (20) of the plate 12D is provided is wider in area than the region of the above-mentioned first embodiment on which the space 20B (20) is provided. Because of this, according to the third embodiment, it is possible to control plasma treatment with respect to the central region of the substrate on the region having the area wider than that of the first embodiment. As a result, it is possible to carry out uniform plasma treatment on a surface of the substrate by negative potential bias.

### Fourth Embodiment

FIG. 6 is an enlarged schematic cross-sectional view showing a substrate mounting unit provided in a plasma processing apparatus according to the fourth embodiment. A substrate mounting unit 10 shown in FIG. 6 represents a state where “a shape forming a space” of the characterizing portion of the invention is provided.

As shown in FIG. 6, in a substrate mounting unit 10E according to the fourth embodiment, a plate 12E has “a shape forming a space”. Particularly, in the substrate mounting unit 10E, a recessed portion is provided at a center region of the plate 12E. A cover 13E is stacked on the plate 12E and therefore a space 20E (20) is formed at the region corresponding to the recessed portion. In the configuration example of the substrate mounting unit 10E shown in FIG. 6, a recessed portion having a predetermined depth d4 is provided at the center region on the top surface of the plate 12E, and the space 20E (20) is positioned between the cover 13E and the plate 12E. Moreover, in the configuration according to the fourth embodiment, a spacer 19E is disposed inside the space 20E (20). For example, the spacer 19E serving as dielectric is arranged inside the space 20E (20). Particularly, as compared with the configuration in which the space 20D (20) is provided in the aforementioned third embodiment, the configuration of the fourth embodiment in which the space 20E (20) is provided is different from the third embodiment in that the spacer 19E serving as dielectric is provided. The other configuration of the substrate mounting unit 10E is the same as the above-described third embodiment. For the spacer 19E, a material having a different dielectric constant can be selected as the dielectric.

According to the configuration of the fourth embodiment, the substrate mounting unit 10E has the space 20E (20) disposed at the center region of the plate 12E and includes the spacer 19E serving as dielectric disposed inside the space 20E (20). Because of this, the substrate mounting unit 10E can finely adjust impedance of the center region of the plate 12E by selecting a material having a different dielectric constant as the spacer 19E serving as dielectric. In the fourth embodiment, even where the shape the region on which the space 20E (20) of the plate 12E is provided is the same as the shape of the region on which the space 20B (20) of the aforementioned first embodiment is provided, the range in which impedance can be adjustable becomes wider. Additionally, even where the shape the region on which the space 20E (20) of the plate 12E is provided is the same as the shape of the region on which the space 20B (20) of the aforementioned first embodiment is provided, there is an advantage in that it is possible to select the range in which impedance can be adjustable. Consequently, according to the fourth embodiment, as compared with the first embodiment, it is possible to control plasma treatment in a state where plasma treatment with respect to the central region of the substrate is further finely adjusted. As a result, it is possible to carry out further uniform plasma treatment on a surface of the substrate by negative potential bias.

Next, plasma etching treatment was carried out with respect to a substrate serving as the processing object by use of a conventional plasma processing apparatus, and uniformity of an etching rate profile on the surface of the substrate due to the plate was evaluated.

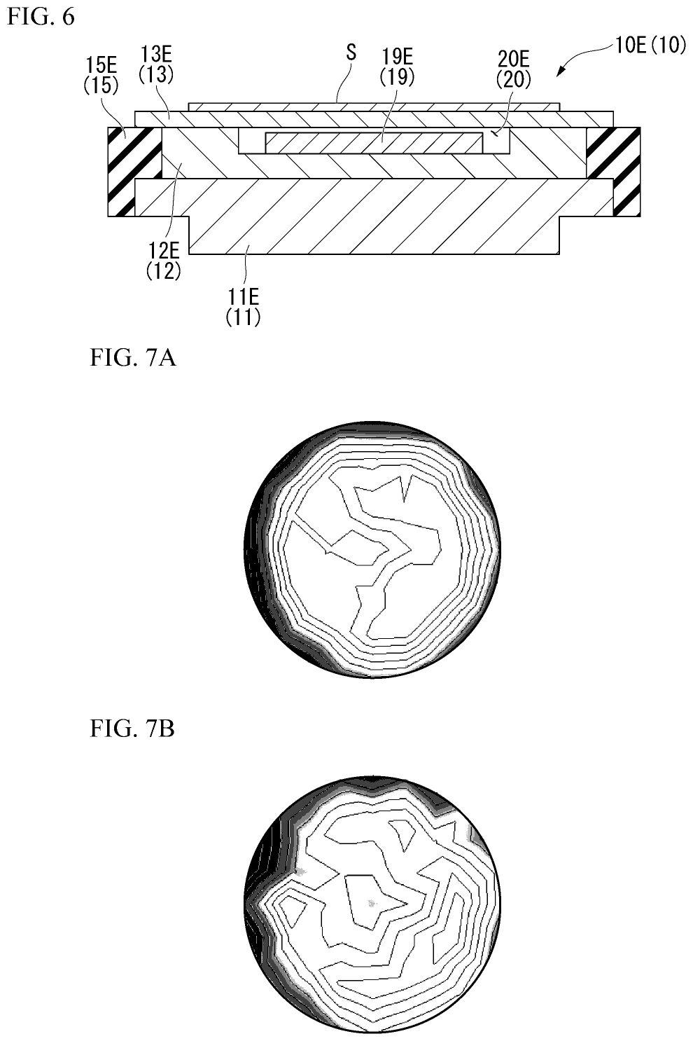

FIG. 7A is for comparison and is a graph showing an etching rate map in the case of a plate having a shape forming a space which is shallow and narrow. FIG. 7A corresponds to the above-described first embodiment. In the structure shown in FIG. 7A, the space 20B of the plate 12B has: φ=100 mm and the depth d1=0.5 mm Plasma etching treatment was carried out with respect to a substrate serving as the processing object by use of the plasma processing apparatus according to the embodiment of the invention, and an etching rate profile on the surface of the substrate due to the plate was evaluated.

FIG. 7B is a graph showing an etching rate map in the case of using the plate having a shape forming a space which is deep and wide. FIG. 7B corresponds to the above-described third embodiment. In the structure shown in FIG. 7B, the space 20D of the plate has: φ=190 mm and the depth d3=1.5 mm.

As the processing object, a substrate was adopted on which a SiO₂ coating and a Ta coating are layered on a Si wafer in this order. The coating which is subjected to etching treatment with respect to the substrate is “Ta coating”. FIGS. 7A and 7B are maps which each shows etching rate on the surface of the substrate when Ta coating was subjected to 30 nm etching.

The conditions of etching treatment in order to obtain the etching rate maps of FIGS. 7A and 7B are common in FIGS. 7A and 7B. In the etching treatment, the following conditions were adopted.

High-frequency power supply: 13.56 MHz

Bias Power: 150 W

Flow rate of Ar gas: 250 sccm

Process pressure: 0.4 Pa

Thickness of electrode cover: 3 mm

Etching thickness (depth) of Ta coating: 30 nm

The following points were apparent from the results shown in FIGS. 7A and 7B.

(A1) As shown in FIG. 7A, in the case of the plate 12B where the shape of the recessed portion forming the space 20B is shallow and narrow, the etching rate map shows a state where the gap between the level curves becomes wide only on the center region of the processing object. Furthermore, the etching rate map shows a state where the gap between the level curves becomes extremely narrow on the peripheral edge region of the substrate. Accordingly, it is apparent that the etching rate map of the plate 12B including the space 20B shows the profile having a significant projected shape.
(A2) As shown in FIG. 7B, in the case of the plate 12D where the shape of the recessed portion forming the space 20D is deep and wide, as compared with FIG. 7A, a state is obtained where the gap between the level curve becomes wide in the etching rate map from the center region to the outer edge region of the processing object. Accordingly, in the case of the plate 12D including the space 20D, it is apparent that uniform etching treatment can be realized on a broad area of the surface of the processing object.

As described above, in the processing apparatus of the processing object according to the embodiment of the invention, it is ascertained that an etching profile on the surface of the processing object can be controlled by changing the shape of the recessed portion forming the space in the plate.

Next, a change rate of an etching rate due to change in the shape of the space was calculated. Here, in the condition in which the space 20D shown in FIG. 7B is larger than the space 20B shown in FIG. 7A (the space 20B (FIG. 7A)<the space 20D (FIG. 7B)), a change rate of the etching rate was calculated by increasing the space provided in the center of the plate.

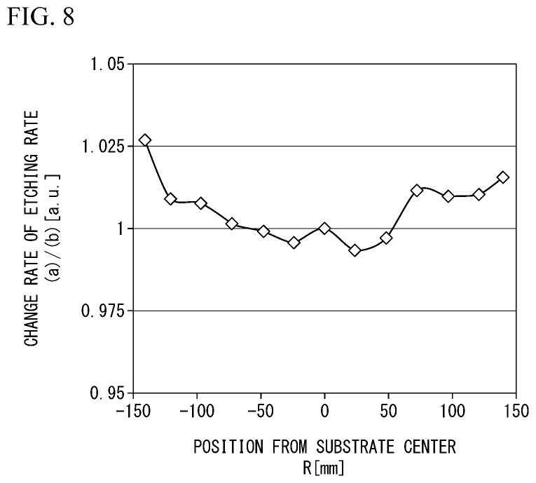

FIG. 8 is a graph showing a relationship between the position from the substrate center (X-axis) and the change rate of the etching rate calculated from the graphs of FIGS. 7A and 7B (Y-axis). Here, the change rate of the etching rate is a numerical value obtained by dividing the result of the etching rate shown in FIG. 7A by the result of the etching rate shown in FIG. 7B. In FIG. 8, the numerical value is represented by “(a)/(b)”. Note that, “(a)/(b)” is calculated by using the numerical value on each of the positions on the X-axis in FIGS. 7A and 7B. The X-axis is the horizontal axis (not shown in the figure) passing through the half point (the center of the circle graph) in the upper and lower direction in the maps shown in FIGS. 7A and 7B.

It is ascertained from the result shown in FIG. 8 that the etching rate of the region close to the center of the plate decreases by increasing the space provided in the center of the plate as shown in the condition (the space 20B (FIG. 7A)<the space 20D (FIG. 7B)).

Moreover, in the condition where the process pressure is a high-pressure and where the etching rate of the outer-edge portion is high, that is, the shape of the etching rate profile is “V-shaped profile”, it is possible to improve uniformity of the profile on the surface by use of the plate (adjustment plate) having the configuration shown in FIG. 4.

Next, in the case where a recessed portion having a different shape is provided on the adjustment plate (plate) and the shape or the capacity of the space is changed, change in the etching rate on the surface of the processing object was evaluated.

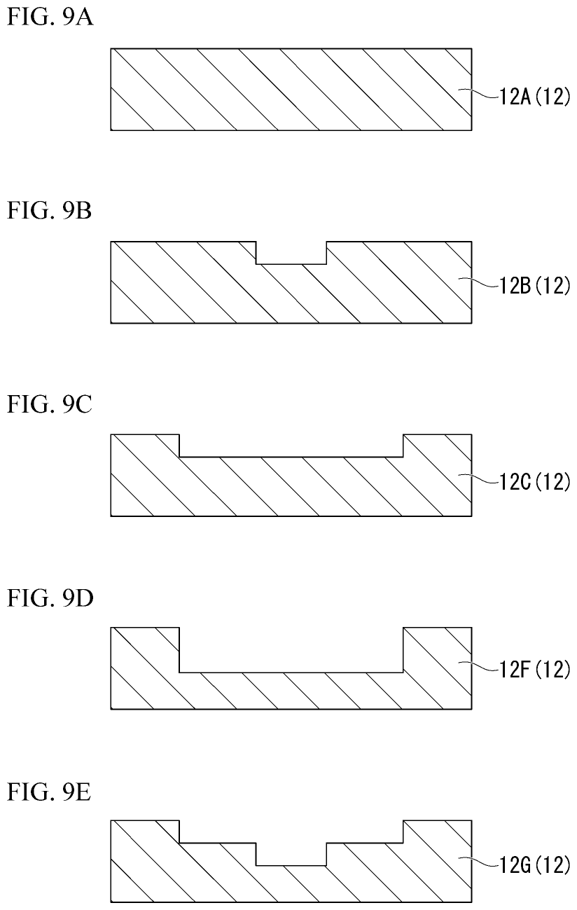

FIG. 9A is an enlarged schematic cross-sectional view showing an adjustment plate in the case where a space is not provided. FIGS. 9B to 9E are enlarged schematic cross-sectional views showing an adjustment plate in the case where a space is provided. In each of FIGS. 9B to 9E, a space having a different condition is provided.

The plate (adjustment plate) shown in FIG. 9A is the plate 12A shown in FIG. 2. Particularly, the plate 12A is in a state before “a shape forming a space” of the characterizing portion of the invention is provided (conventional state).

The plate (adjustment plate) shown in FIG. 9B is the plate 12B shown in FIG. 3. Particularly, the plate 12B has “a shape forming a space”. Particularly, in the plate (adjustment plate) shown in FIG. 9B, the recessed portion is provided at the center region of the plate 12B. Accordingly, the space 20B is present in a shallow and narrow region on the center region of the plate 12B.

The plate (adjustment plate) shown in FIG. 9C is the plate 12D shown in FIG. 5. Particularly, the plate 12D has “a shape forming a space”. Particularly, in the plate (adjustment plate) shown in FIG. 9C, the recessed portion is provided at the center region of the plate 12D. Accordingly, the space 20D is present in a shallow and wide region on the center region of the plate 12D.

In the plate (adjustment plate) shown in FIG. 9D, the plate 12F has “a shape forming a space”. Particularly, in the plate (adjustment plate) shown in FIG. 9D, the recessed portion deeper than that of the plate shown in FIGS. 9B and 9C is provided at the center region of the plate 12F. Accordingly, the space is present in a deep and wide region on the center region of the plate 12F.

In the plate (adjustment plate) shown in FIG. 9E, the plate 12F has “a shape forming a space”. Particularly, a recessed portion having a two-step depth is provided at the center region of the plate 12G. Accordingly, the center region of the plate 12G has a stepwise space. This space is deep at the central region of the plate 12F, is shallow at the outer-edge portion of the plate 12F, and present in a wide region.

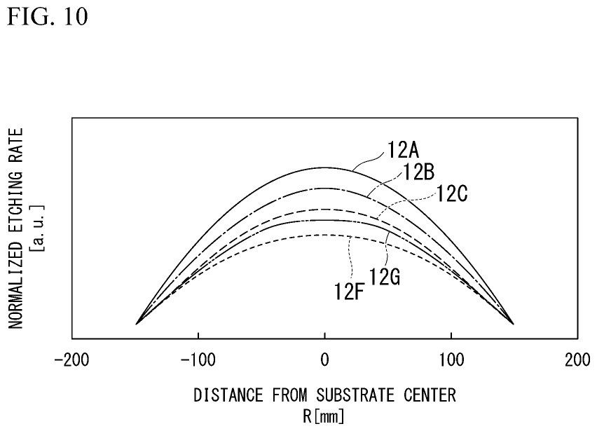

FIG. 10 is a graph showing a relationship between the position from the substrate center and a normalized etching rate in the case of each of various adjustment plates shown in FIGS. 9A to 9E.

It is ascertained from the results shown in FIG. 10, an etching rate on the surface of the processing object can be controlled by changing the shape or the capacity of the space due to provision of the recessed portions having various shapes shown in FIGS. 9A to 9E to the plate.

As described above, the plasma processing apparatus according to the embodiment were explained, the invention is not limited to the embodiments, and various modifications may be made insofar as they do not depart from the scope of the invention.

### INDUSTRIAL APPLICABILITY

The invention is widely applicable to a plasma processing apparatus. For example, the plasma processing apparatus of the invention is preferably used in the case where a processing object has a large area, the case where it is necessary to adjust conditions (process pressure, processing gas) of etching treatment with respect to a processing object, or the like.

### DESCRIPTION OF REFERENCE NUMERALS

AT second electrode (antenna coil), D isolation valve, G gas introduction device, P pumping device, S processing object (substrate), 17 chamber, 11 first electrode (support base), 12 plate (adjustment plate), 13 cover (electrode cover), 16a first matching box (M/B), 16b first power supply, 17 chamber, 18a second matching box (M/B), 18b second electrode.

1. A plasma processing apparatus comprising:
a chamber that has an internal space able to be depressurized and is configured such that a processing object is subjected to plasma treatment in the internal space;
a first electrode that is disposed in the chamber and on which the processing object is to be mounted;
a first power supply that applies a bias voltage of negative potential to the first electrode;
a spiral shaped second electrode that is disposed outside the chamber and is disposed so as to face the first electrode with an upper lid of the chamber interposed therebetween;
a second electrode that applies a high-frequency voltage to the second electrode;
a gas introduction device that introduces a processing gas into an inside of the chamber; and
a pumping device that depressurizes the inside of the chamber, wherein
a plate having a shape forming a space and a cover provided to cover the plate are stacked in order and disposed between the first electrode and the processing object.

2. The plasma processing apparatus according to claim 1, wherein the space is formed by: an inner surface forming a recessed portion provided on the plate; and one surface of the cover which is located close to the plate.

3. The plasma processing apparatus according to claim 1, wherein the space is disposed at a center region of the cover.

4. The plasma processing apparatus according to claim 1, wherein the space is disposed at an outer edge region of the cover.

5. The plasma processing apparatus according to claim 1, further comprising:
a spacer disposed inside the space.
